(19) United States
(12) Patent Application Publication
(10) Pub. No.: US 2012/0242938 A1
(43) Pub. Date: Sep. 27, 2012

(54) METHODS FOR MANUFACTURING LCD SUBSTRATES AND LCDS

(75) Inventors: Tsan-Jen CHEN, Chu-Nan (TW); Bi-Ly LIN, Chu-Nan (TW)

(73) Assignee: CHIMEI INNOLUX CORPORATION, Chu-Nan (TW)

(21) Appl. No.: 13/243,866

(22) Filed: Sep. 23, 2011

(30) Foreign Application Priority Data
Mar. 25, 2011 (TW) 100110325

(51) Int. Cl. G02F 1/1335; G03F 7/20

(52) U.S. Cl. 349/106; 430/320

(57) ABSTRACT

Disclosed is a method for manufacturing an LCD substrate, including forming an alignment material layer on a transparent substrate. The transparent substrate is located on an exposure platform, wherein the exposure platform surface includes a patterned structure thereon. The photo alignment aligns the alignment material layer corresponding to the patterned structure, thereby patterning the alignment material layer to form a multi-domain alignment structure.

### CROSS REFERENCE TO RELATED APPLICATIONS

This Application claims priority of Taiwan Patent Application No. 100110325, filed on Mar. 25, 2011, the entirety of which is incorporated by reference herein.

### BACKGROUND OF THE INVENTION

1. Field of the Invention

The invention relates to a photo alignment process, and in particular relates to a photo alignment process aligning an alignment material layer on a transparent substrate.

2. Description of the Related Art

Processes for manufacturing standard TFT-LCDs can be classified into three major segments. The first segment is the so-called array process, which manufactures a color filter substrate and an array substrate, which drives the display signals. The second segment is the so-called cell process which controls, fills, and seals liquid crystals between the array substrate and the color filter substrate to complete a liquid crystal panel. The third segment is the so-called module process, wherein a polarizer, a back-light module, and the liquid crystal panel are assembled. The most critical step of the three segments is the alignment of liquid crystals in the cell process. Liquid crystal alignment not only determines the order and direction of the arrangement of the liquid crystals, but also effects display quality properties such as view angle, response speed, contrast ratio, and color performance.

Liquid crystal alignment means that the liquid crystals are oriented to a direction, such that all or part of the liquid crystal may be arranged in a same direction. When an electric field is applied to drive the liquid crystals, part or all of the liquid crystals of the same direction may similarly and simultaneously rotate. Therefore, fast and consistent images can be displayed by an LCD. General alignment processes can be classified into a rubbing process or non-rubbing processes. The major non-rubbing process is a photo alignment process.

The alignment material layer of the photo alignment process can be a polymer film such as a polyimide (PI) film and the likes. An anisotropic UV light is applied to the polymer film, such that polymers of the film surface will be anisotropically polymerized, isomerized, or decomposed. Therefore, the anisotropically distributed Van Der Waals Force on the film surface may induce the liquid crystals to be arranged toward a specific direction. The anisotropic UV light which is most utilized, is a linear polarized UV light, which is polarized by a polarizer. Because UV light has higher anisotropic properties, it may efficiently induce an anisotropic photo reaction on the polymer film. As such, anisotropic UV light is widely applied in the photo alignment process. Photo alignment processes with excellent uniformity have been developed for almost ten years.

Similar to general exposure processes, the photo alignment process requires a high critical dimension (CD) standard. A minor misalignment will dramatically degrade the display quality of products. Because the alignment material layer is transparent, the conventional photo alignment aligns to the alignment material layer corresponding to a pattern under the alignment material layer. In a case of an array substrate, the photo alignment process may align the alignment material layer corresponding to metal lines (e.g. gate lines and data lines) under the transparent alignment material layer. In a case of color filter substrate, the photo alignment process may align the alignment material layer corresponding to a black matrix (BM) pattern under the transparent alignment material layer. If a color filter on array (COA) substrate or an array on color filter (AOC) substrate is adopted as one substrate of the LCD, the substrate opposite to the COA substrate (or the AOC) substrate must be a transparent substrate without any alignment reference (e.g. metal lines or BM) for the photo alignment process. Accordingly, the photo alignment process can be used for an alignment material layer on the AOC substrate (or the AOC substrate) to form a multi-domain alignment structure. But, for an alignment material layer on the transparent substrate, the photo alignment process cannot be used due to the lack of an alignment reference. In other words, the photo alignment process cannot be applied to an LCD including the AOC substrate or COA substrate.

Accordingly, manufacturing of an LCD including an AOC substrate or a COA substrate should be introduced, wherein a photo alignment process is performed without largely changing the conventional process steps.

### BRIEF SUMMARY OF THE INVENTION

One embodiment of the disclosure provides a method for manufacturing an LCD substrate, comprising: forming an alignment material layer on a transparent substrate; locating the transparent substrate on an exposure platform, wherein the exposure platform has a surface, and the surface has a patterned structure thereon; processing a photo alignment to the alignment material layer, wherein the photo alignment corresponds to the patterned structure; and patterning the alignment material layer to form a multi-domain alignment structure.

One embodiment of the disclosure provides an LCD, comprising: a transparent substrate having a multi-domain alignment structure thereon, wherein no TFT array layer or color filter layer is disposed between the multi-domain alignment structure and the transparent substrate; an opposite substrate having another multi-domain alignment structure thereon, wherein the opposite substrate is a color-filter on array substrate or an array on color-filter substrate; and a liquid crystal layer disposed between the transparent substrate and the opposite substrate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a top view of a transparent substrate in one embodiment of the disclosure;

FIG. 2 shows a cross-sectional view of a transparent substrate in one embodiment of the disclosure;

FIG. 3 shows a top view of an exposure platform in one embodiment of the disclosure;

FIG. 4 shows a top view of a transparent substrate in one embodiment of the disclosure; and

FIGS. 5A-5B show cross-sectional views of liquid crystal displays in embodiment of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

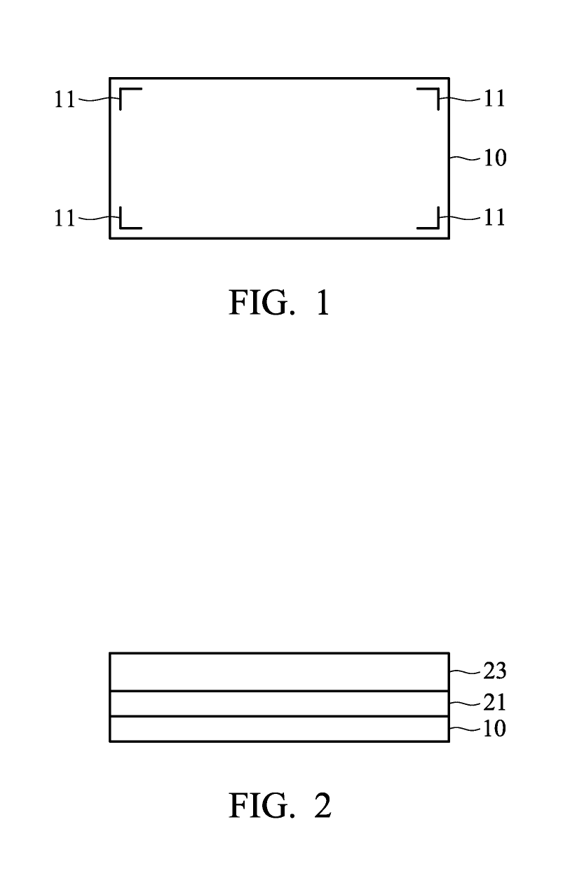

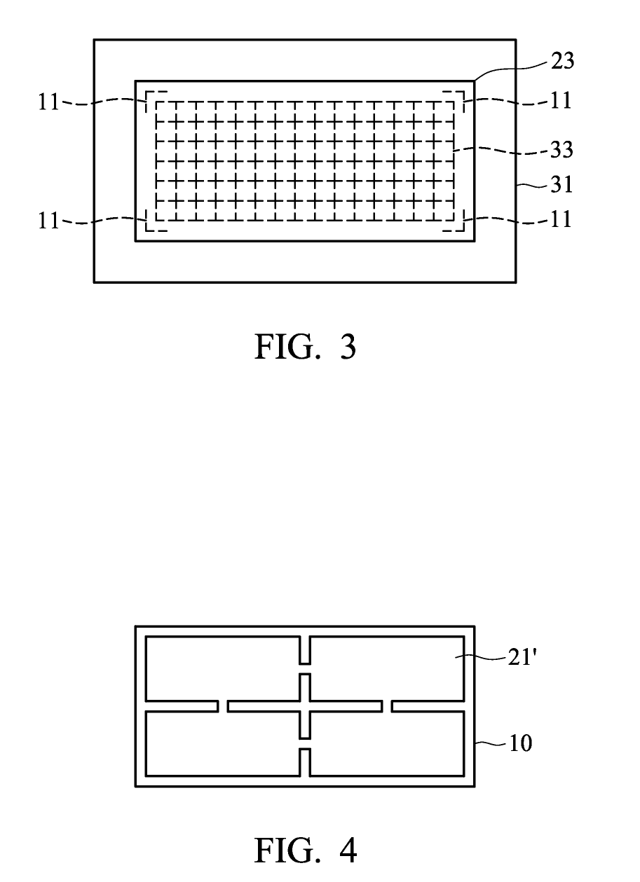

FIG. 1 shows a top view of a transparent substrate in one embodiment of the disclosure. As shown in FIG. 1, laser notches 11 formed on the transparent substrate 10 serve as marks. It should be understood that the laser notches 11 are located on four corners of the transparent substrate 10 in FIG. 1, however, the laser notches 11 can be formed on other positions of the transparent substrate 10 (such as side or center) which do not shield the display regions of pixels. As shown in FIG. 2, a transparent conductive layer 21 and an alignment material layer 23 are sequentially formed on the transparent substrate 10. There is no color filter layer or TFT array layer disposed between the alignment material layer 23 and the transparent substrate 10. The transparent conductive layer 21 may serve as a sheet of a common electrode layer in the LCD described below. In one embodiment, the alignment material layer 23 can be composed of polyimide (PI). As shown in FIG. 3, a photomask 33 is then put on a surface of an exposure platform 31, and the transparent substrate 10 with the transparent conductive layer 21 and the alignment material 23 formed thereon is put on the photomask 33. The exposure platform 31 is a platform for placing of the transparent substrate during the photo alignment process. As such, the exposure platform 31 may determine the position of the transparent substrate 10 by the laser notches 11 on the transparent substrate 10. Subsequently, the photo alignment process aligns the alignment material layer 23 corresponding to a pattern of the photomask 33 under the transparent substrate 10, thereby patterning the alignment material layer 23 to form a multi-domain alignment structure of high accuracy. The multi-domain alignment structure means that each pixel has at least two domains of alignment structures with different alignment directions. The photo alignment process must be performed with a patterned structure such as the photomask 33 on the surface of the exposure platform 31. In one embodiment, the patterned structure on the surface of the exposure platform 31 can be a broken photomask (or a photomask recovered from a process which has been discontinued). It is not necessary to produce a new photomask for the photo alignment process. In another embodiment, the photomask 33 can be replaced by other patterned structures, such as a print. The print can be cleaned and removed after the photo alignment process, such that other exposure processes will not be influenced by the print. In FIG. 3, the photomask 33 is located under and is smaller than the transparent substrate 10. In other embodiments, the photomask 33 is larger than the transparent substrate 10. In some embodiments, the photomask 33 can be located in a region outside of the transparent substrate 10, wherein the photo alignment process may still align the alignment material layer 23 corresponding to the photomask 33.

In the described embodiment, the laser notches 11 serve as marks to determine the position of the transparent substrate 10 on the exposure platform 31. In another embodiment, the transparent conductive layer 21 is patterned by a lithography process to form a patterned conductive layer 21′, as shown in FIG. 4. Similar to the laser notches 11 in FIG. 1, the patterned conductive layer 21′ in FIG. 4 may serve to determine the position of the transparent substrate 10 on the exposure platform 31. When the patterned conductive layer 21′ is formed on the transparent substrate 10, the laser notches 11 can be omitted. The patterned conductive layer 21′, as well as the transparent conductive layer 21 in FIG. 2, may serve as a common electrode layer of an LCD described below. It should be understood that the patterned conductive layer 21′ includes four connected blocks in FIG. 4, however, the number and size of the blocks are not limited to the manner shown in FIG. 4. Note that the patterned conductive layer 21′ only serves as the common electrode layer, not a TFT array layer. Subsequently, the alignment material layer 23 is formed on the patterned conductive layer 21′. The transparent substrate 10 with the patterned conductive layer 21′ and the alignment material 23 formed thereon is put in the exposure platform 31, wherein the surface of the exposure platform 31 has a patterned structure such as the photomask 33 or the print thereon. The photo alignment process thereafter is similar to previous description and omitted here.

In a further embodiment, the mark (e.g. the laser notches 11 or the patterned conductive layer 21′) on the transparent substrate 10 can be omitted. Meanwhile, the side or corner of the transparent substrate 10 can be directly used to determine the position of the transparent substrate 10 on the exposure platform 31. Next, the photo alignment process aligns to the alignment material layer 23 corresponding to the patterned structure such as the photomask or the print on the surface of the exposure platform 31, thereby patterning the alignment material layer to form the multi-domain alignment structure.

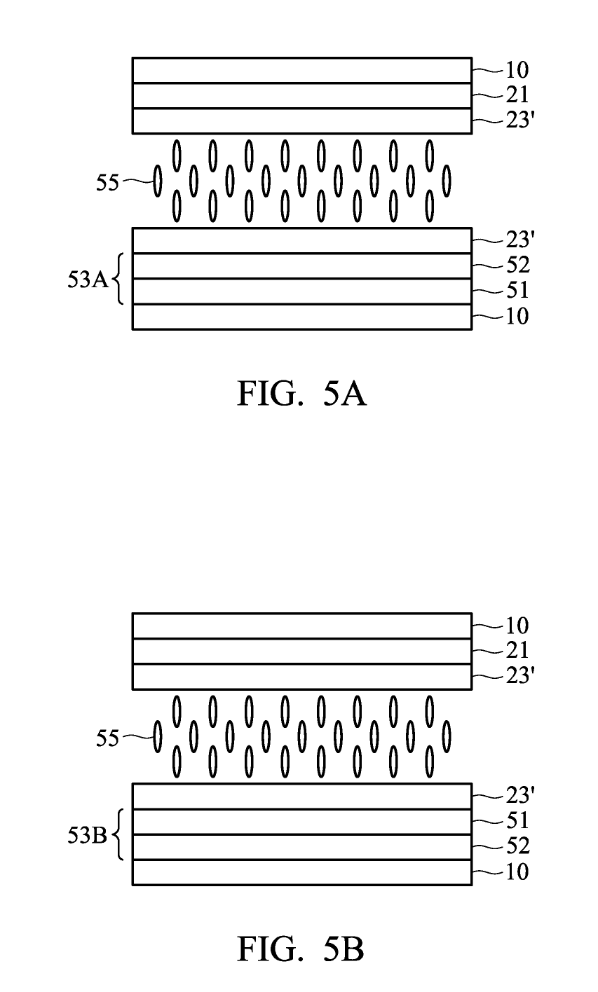

An AOC substrate and a COA substrate inherently have patterned structures such as the electrode pattern and the BM pattern, respectively. As such, a general photo alignment process can be performed to pattern the alignment material layer 23 to form the multi-domain alignment structure 23′ on the AOC substrate 53A or the COA substrate 53B. The AOC substrate 53A (or the COA substrate 53B), including the multi-domain alignment structure 23′ thereon, serve as an opposite substrate of the transparent substrate 10 including the multi-domain alignment structure 23′ thereon. The liquid crystal 55 is injected into a space between the transparent substrate 10 and the AOC substrate 53A (or the COA substrate 53B), thereby completing an LCD as shown in FIG. 5A (or FIG. 5B). As described above, the AOC substrate 53A is the array on color filter substrate, wherein the array layer 52 is formed on the color filter layer 51. The COA substrate 53B is the color filter on array substrate, wherein the color filter layer 51 is formed on the array layer 52.

Accordingly, the disclosure provides a method to form a multi-domain alignment structure on a transparent substrate by a photo alignment process. The patterned structure such as a photomask or a print on an exposure platform may serve as the reference for alignment of a photo alignment process with high accuracy.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing an LCD substrate, comprising:
forming an alignment material layer on a transparent substrate;
locating the transparent substrate on an exposure platform, wherein the exposure platform has a surface, and the surface has a patterned structure thereon;
processing a photo alignment to the alignment material layer, wherein the photo alignment corresponds to the patterned structure; and
patterning the alignment material layer to form a multi-domain alignment structure.

2. The method as claimed in claim 1, wherein the patterned structure comprises a photomask or a print.

3. The method as claimed in claim 1, further comprising a mark on the transparent substrate.

4. The method as claimed in claim 3, wherein the mark comprises a laser notch.

5. The method as claimed in claim 3, wherein the mark comprises a patterned conductive layer disposed between the transparent substrate and the alignment material layer.

6. An LCD, comprising:
a transparent substrate having a multi-domain alignment structure thereon, wherein no TFT array layer or color filter layer is disposed between the multi-domain alignment structure and the transparent substrate;
an opposite substrate having another multi-domain alignment structure thereon, wherein the opposite substrate is a color-filter on array substrate or an array on color-filter substrate; and
a liquid crystal layer disposed between the transparent substrate and the opposite substrate.

7. The LCD as claimed in claim 6, further comprising a mark on the transparent substrate.

8. The LCD as claimed in claim 7, wherein the mark comprises a laser notch.

9. The LCD as claimed in claim 7, wherein the mark comprises a patterned conductive layer disposed between the transparent substrate and the alignment material layer.
